(19) United States
(12) Patent Application Publication
(10) Pub. No.: US 2007/0144901 A1
(43) Pub. Date: Jun. 28, 2007

(54) Pulsed cathodic arc plasma

(76) Inventors: Terje Asbjorn Skotheim, Tucson, AZ (US); Uladzimir Uladzimiravich Sheleh, Smorgon (BY); Grigory Grigorievich Kirpilenko, Moscow (RU)

Correspondence Address: VENABLE, CAMPILLO, LOGAN & MEANEY, P.C., 1938 E. OSBORN RD, PHOENIX, AZ, 85016-7234, US

(21) Appl. No.: 10/598,217

(22) PCT Filed: Mar. 15, 2005
(86) PCT No.: PCT/US05/08437

§ 371 Date: Aug. 21, 2006

Related U.S. Application Data
(60) Provisional application No. 60/552,923, filed on Mar. 15, 2004.

(51) Int. Cl. C23C 14/00

(52) U.S. Cl. 204/298.41

(57) ABSTRACT

The present invention provides a pulsed plasma arc source capable of applying diamond-like carbon coatings, other hard wear resistant coatings or metal coatings to a substrate. The pulsed plasma arc source is based on the use of a magnetron sputtering system for initiation of the pulsed arc discharge. The pulsed plasma arc source can be scale up to coat large substrates.

### FIELD OF THE INVENTION

The present invention relates to an apparatus for applying coatings of materials in vacuum and more specifically to a pulsed arc plasma source.

### BACKGROUND OF THE INVENTION

Pulsed arc discharge, generated between graphite electrodes in vacuum with pressure lower than 10⁻⁴ torr, which is necessary for the existence of cathode spots on the cathode surface, produces the hardest and most wear-resistant amorphous diamond-like carbon coatings, knows as tetrahedral amorphous carbon, or ta-C. The hardness and wear-resistance of such coatings are close to that of crystalline diamond and exceed that of other types of diamond-like carbon coatings obtained by other methods by a factor of 2-4 (A. Grill, Diamond and Related Materials Vol. 8 (1999) pp. 428-434).

Several methods and apparatus to obtain such coatings are known, where the ion plasma flow is generated by a standard method and accelerated towards the substrate by an electric field. To form the diamond-like phase in the deposited coating the mean energy of the carbon ions should be higher than the energy of carbon-carbon bonds in the diamond lattice (14.6 eV) and should not be higher than the threshold for defect formation (60 eV) (J. Robertson, Materials Science and Engineering Vol. R 37 (2002) pp. 129-281).

In one method, a pulsed arc apparatus is applied, where the carbon plasma is generated as a result of an electric discharge in vacuum on a graphite cathode resulting in erosion of the cathode followed by evaporation of cathode material (S. Aisenberg and R. Chabot, J. Vac. Sci. Tech., Vol. 18 (1973) p. 852; I. I. Aksenov et al., Sov. Phys. Tech. Phys. Vol. 25(9), September 1980). The closest prior art consists of an apparatus wherein the consumable graphite cathode and anode having a common geometrical axis are electrically coupled to a capacitive storage shunted to a dc charger, and an arc striking means disposed in the vacuum chamber and connected to an initiation unit (E. I. Tochitsky et al., Surface and Coating Technology, Vol. 47 (1991) pp. 292-298; U.S. Pat. No. 5,078,848; A. I. Maslov et al., Instruments and Experiment Technique, Vol. 3 (1985) pp. 146-149).

The methods and apparatus described in the prior art have the following critical drawbacks:

Short service life of the apparatus for one set of graphite electrodes, which is insufficient for operation in a manufacturing environment. Because of erosion of the cathode and undesirable carbon deposition on the anode, leading to a closing of the gap between the electrodes, the maximum number of pulses per set of electrodes is less than 250,000. With a maximum frequency of 15 Hz, this corresponds to 4.5 hours of continuous operation before the electrodes must be replaced, resulting in undesirable downtime of production;

A too large and uneconomical consumption of electrodes fabricated from low-porosity, expensive graphite material;

A too small deposition area of uniform thickness on the coated articles. This area is correlated with the diameter of the cathode, which is equal to approximately 30 mm. The coated area is restricted by path length-lifetime of the cathode spots on the end surface of the cathode during the pulsed discharge time. In order to enlarge the diameter of the cathode, the voltage must be increased, but such a voltage increase in the capacitive storage above the predetermined threshold leads to uncontrolled electrical breakdowns between the electrodes, resulting in contamination of the carbon plasma and deterioration of the properties of the diamond-like coating formed.

In the apparatus design described in Russian Patent No. 2153782 (A. Kolpakov et al., (2000)), to increase the deposition area with homogeneous thickness on the treated articles an array of cathode units were applied. However, in order to have easy access to the graphite electrodes for replacement, the ignition units of each assembly and the cathodes with auxiliary anodes are not separated and mounted vertically in close proximity. As a result, neighboring assemblies can be activating unexpectedly, resulting in incomplete pulse of carbon plasma development. Besides, a fixed and restricted number of ignition units lowers the reliability of the main pulsed arc discharge. The graphite electrodes are worn unevenly, which shortens the service life of electrodes and of the apparatus itself. Another critical disadvantage is that to achieve high productivity of every cathode assembly requires separate power supplies to be provided for each assembly.

In the apparatus described in Patent Application PCT WO 02/062113 A1 (Y. Kolpakov et al. (2002)), based on a single cathode assembly, a scanning method is provided to enlarge the deposition area of uniform coating. The method is a controlled tracking of plasma flow in a vertical plane during deposition by using deflecting coils to scan the ion beam. This invention would make it possible to extend the uniform coating thickness by a factor of 3, up to 90 mm. But the service life of graphite electrodes is still short and the rate of deposition is lowered by a factor of 3 because the same carbon plasma flow now covers 3 times the area.

Another method applies laser pulses to initiate the main pulse. A laser beam scans the surface of a graphite cathode cylinder (U.S. Pat. No. 338,778) to evaporate the cathode material. The height of the cylinder may be several tens of centimeters and coincide with the dimension of the article being coated. The cathode may have a diameter sufficiently large to provide long life before replacement. The drawback of this apparatus is its low deposition rate and low productivity as well as high level of complexity and high cost.

Traditional methods of magnetron carbon sputtering (M. Witold et al., J. Vac. Sci. Tecnol., Vol A11 (6) (1993) pp. 2980-2984); V. M. Ievlev et al., 5-th International Conference F and C (1998), abstract, p. 371) has low sputtering rate and do not provide sufficiently thick diamond-like carbon films with hardness and wear-resistance close to that obtained by pulsed arc discharge methods. However, this method is used in industrial mass production for a wide spectrum of coatings. It has a highly efficient utilization of sputtering material as well as simple and serviceable structure. Traditional magnetron systems typically operate at a gas pressure of 10⁻² torr.

In a ring planar magnetron the cathode in the form of a disk is mounted above stationary magnets or a solenoid, which create the magnetic field above the cathode surface. The direction of the magnetic field is parallel to the plane of the cathode. The anode is above the cathode, and the applied electric field is perpendicular to the plane of the cathode, such that crossed magnetic and electric fields are formed in the zone near the cathode, wherein electrons colliding with gas molecules ionize the gas so that a discharge (magnetron discharge) is excited and a circular (toroidal) zone of plasma is formed. Positive ions are accelerated towards the cathode and bombard its surface, thus sputtering material from the target cathode surface. One long magnetron with cathode of a height to fit the vacuum chamber is capable of coating the entire volume of the chamber and has a target service life of several days (Film Deposition in Vacuum. Collected Volume. “Technologies of Semi-Conductive Instruments and Articles of Microelectronics” Book 6, Moscow (1989)).

Approximately ten years ago magnetron systems were developed capable of operating under an argon pressure of 2×10⁻⁴ (V. Stambouli et al., Thin Solid Films Vol. 193/194 (1990) pp. 181-188; D. W. Hoffman, J. Vac. Sci. Technol. Vol. A 12(4) (1994) pp. 953-961) equal to the vacuum of stable pulsed arc discharge. To fabricate carbon films with features close to those obtained by pulsed arc deposition, a non-balanced magnetron was used (U.S. Pat. No. 6,599,492), but the deposition rate was much lower than with the pulsed arc deposition method.

A known method of fabricating hydrogenated diamond-like carbon films by magnetron sputtering is based on decomposition in acetylene-krypton plasma under a pressure of 10⁻³ torr (A. V. Balakov and E. A. Konshina, Journal of Optical-Mechanical Industry, Vol. 9 (1982) pp. 52-59; A. V. Balakov and E. A. Konshina, Journal of Technical Physics Vol. 52 (1982) pp. 810-811). A conventional magnetron with a graphite cathode and graphite ring anode was used. This system achieves a high degree of ionization of gas molecules. In this system acetylene is the hydrocarbon plasma source for deposition of the carbon coating. Ionized krypton promotes the destruction of acetylene. Extrusion of ions in the anode zone towards the substrate is provided by applying a negative bias potential to the substrate. The deposition rate is defined by hydrocarbon plasma flow. Graphite cathode and anode promote the formation of coatings free of impurities. The adhesion coefficient of atoms/ions of krypton (or argon, another inert gas that may be used) is lower by a factor of 10² than that of atoms of metal or carbon and do not enter into the composition of the coating (A. Evshov and L. Pekker, Thin Solid Films, Vol. 289 (1996) pp. 140-146). Coatings obtained by this method are characterized by lower hardness and wear-resistance compared with the coatings obtained by pulsed arc method.

### SUMMARY OF THE INVENTION

The object of the present invention is to provide a pulsed arc plasma source, the design of which makes it possible to obtain an efficiency of the cathode assembly similar to that of magnetrons, and energy characteristics and plasma density comparable to pulsed arc discharge in vacuum. The source combines the best characteristics of magnetron sputtering and pulsed arc discharge.

The object is achieved with a pulsed plasma arc source design comprising:

a magnetron with a consumable target of metal, graphite or other material, including composite materials;

an anode having a common geometrical axis and being electrically coupled to a capacitive storage shunted to a dc charger;

a main discharge gap (cathode—main anode), which is the working gap, wherein the main arc discharge pulse is generated;

an auxiliary discharge gap (cathode—auxiliary anode), which serves to initiate the arc discharge in the main discharge gap and represents itself a magnetron sputtering-initiation system, wherein a magnetron discharge in crossed electric and magnetic fields initiates the sputtering of target material and maintains cathode spots on the surface of the target until the pulsed arc discharge is triggered;

a means for generating a magnetic field, comprising permanent magnets or one main solenoid in the magnetron sputtering-initiation system;

a means for controlling the carbon (or metal) plasma beam with one solenoid of the ion-optical system being accommodated inside the vacuum chamber in front of the main anode and being electrically connected with the main anode;

a means for flexible control of magnetic and electric fields comprising at least one auxiliary solenoid in the magnetron sputtering-initiation system adjacent to the main solenoid;

a means for flexible control of the plasma beam comprising one external solenoid of the ion-optical system being accommodated outside the vacuum chamber, above and around the main and auxiliary anodes and being electrically connected with the main anode;

a means for storage of electrical power from a dc power supply source having at least two storage systems comprising electrical capacitors with capacitance large enough to store the required amount of energy for operation of the magnetron sputtering-initiation system and for initiation of pulsed arc discharge. One storage system is connected to the corresponding electrodes of the auxiliary discharge gap (cathode-auxiliary anode), the other storage system is directly connected to the corresponding electrodes of the main discharge gap (cathode-main anode);

a control means for the pulsed arc plasma source, wherein a power supply channel for the auxiliary solenoid of the magnetron sputtering-initiation system is synchronized with delay relative to the fronts of the initiating pulses in the auxiliary discharge gap. It serves to compensate for the magnetic field generated by the main solenoid of the magnetron sputtering-initiation system;

The preferred shape of the consumable cathode target is a circle, ellipse or polygon.

The preferred shape of the main anode and auxiliary anode is a hollow cylinder or a hollow prism, the side-wall of said cylinder or prism being formed by rods with the longitudinal axis of the rods being parallel with the longitudinal axis of the cylinder or prism, as well as a set of interconnected rings (torous).

The present invention is useful as a manufacturing system for production of metal, diamond-like carbon or other hard and wear resistant protective coatings in vacuum on various articles, including articles of extended size, in order to extend life of such items as cutting, shaping and measuring tools, wear units and parts of machines, as well as to improve biological compatibility of implants in medicine, and to extend the life of video and audio heads in electronics.

### BRIEF DESCRIPTION OF THE DRAWINGS

The main features of the invention will become apparent upon examination of the accompanying drawings, wherein:

FIG. 1, FIG. 2 and FIG. 3 show a schematic view of the pulsed arc plasma source in accordance with the invention.

### DETAILED DESCRIPTION OF THE INVENTION

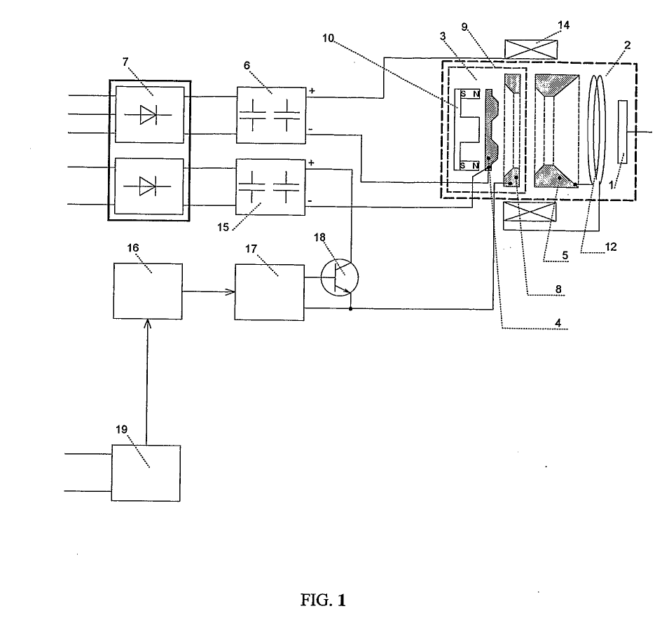

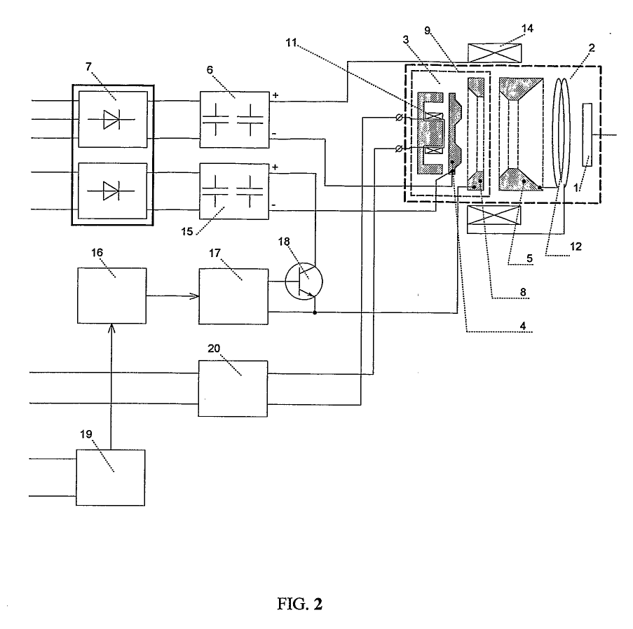

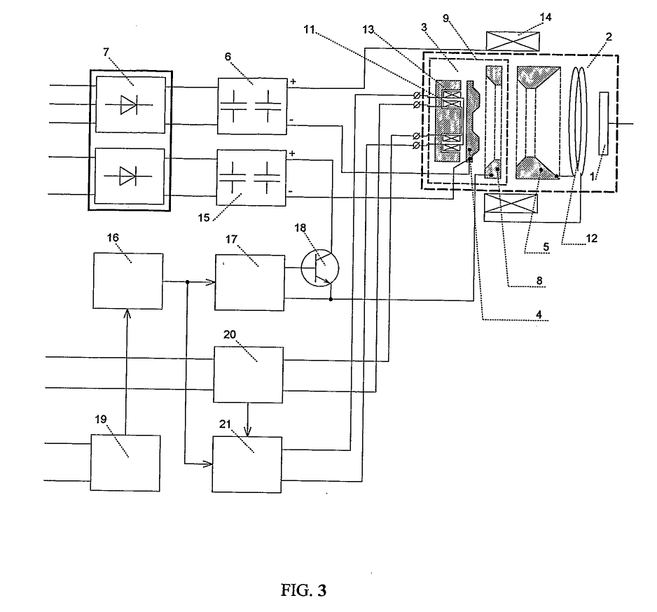

Referring to FIG. 1, FIG. 2, and FIG. 3, the pulsed arc source of the invention, capable of depositing a metal, diamond-like carbon or other hard and wear resistant coatings on treated articles 1 is accommodated in a vacuum chamber 2 and comprises a magnetron 3 with a consumable target made from graphite or other material, including composites; a cathode 4 and a main anode 5, both having a common geometrical axis, and electrically connected to a capacitive storage system 6 shunted to a dc charger 7; an auxiliary anode 8; a magnetron sputtering-initiating system 9 for the main discharge pulse; a means for generation of magnetic field comprising either permanent magnets 10, or one main solenoid 11, in the magnetron sputtering-initiation system; one solenoid 12 of the ion-optical system for controlling the plasma beam and located inside the vacuum chamber in front of the anode and being electrically connected with the anode, at least one auxiliary solenoid 13 for flexibly controlling magnetic and electric fields; an external solenoid 14 of the ion-optical system located outside the vacuum chamber, in front of and surrounding the main and auxiliary anodes and being electrically connected with the anode; a means for storage of electrical power from a dc power supply source 7 having at least one auxiliary storage system 15 for initiating discharge and having a capacitance large enough to store the required amount of energy for operation of the magnetron sputtering-initiation system and for initiation of the pulsed arc discharge; a control means for pulsed plasma source comprising a pulse-train generator 16, a control circuit 17 for triggering the initiating discharge circuit, a trigger 18 for initiating the discharge circuit, a switchboard 19 with switched power supply channel for the auxiliary solenoid 11 of the magnetron sputtering-initiation system, a power supply unit 20 for the main solenoid 11, and a power supply unit 21 for solenoid 13.

The pulsed arc plasma source operates in the following manner: Upon evacuating the vacuum chamber to a pressure of 5×10⁻⁶-5×10⁻⁵ torr, argon is backfilled to a pressure of 6×10⁴-6×10⁻³ torr. The storage systems 6 and 15 are charged from the dc charger beforehand or at the same time. A stand-by storage system 15 is charged to a voltage level much higher than the level under which the independent arc discharge is excited in the crossed electric and magnetic fields of the magnetron sputtering-initiation system. Initially, the induction of a magnetic field on the cathode surface is high enough to generate magnetron discharge in the crossed electric and magnetic fields of the magnetron sputtering-initiation system. There is an electric field in the main discharge gap and the auxiliary discharge gap as the potential difference between cathode 4 and main anode 5 is equal to the voltage of the charged storage system. But this field intensity is not sufficient to develop the magnetron discharge on the cathode surface.

Generator 16 of the control unit generates and sends a control pulse to initiate the vacuum arc discharge. The control pulse closes the trigger 18, the trigger connects the charged storage battery 15 to the corresponding electrodes 4 and 8 of auxiliary discharge gap for 2-3 msec and the current excites the magnetron discharge in vacuum in the residual argon atmosphere. The plasma flow of the magnetron discharge is excited at the surface of the target cathode 4 in the crossed electric and magnetic fields. The cathode surface is actively bombarded by argon ions. The sputtering of cathode material starts and the electrical conductance of the auxiliary discharge gap increases. The process develops in an avalanche-like manner, and, since the internal resistance of the storage system is low (that promotes high density carbon plasma near the target, this density dissipates along the restricted surface of cathode by plasma flow) cathode spots are generated on the surface of the cathode.

Cathode spots of the arc discharge being generated on the surface transform the electrical discharges in the auxiliary discharge gap into arc discharges. The transformation is followed by the ejection of ionized atoms of cathode material into the main discharge gap. It raises the electrical conductance of the main discharge gap and promotes the development of the main arc discharge. High energy is required to generate the main discharge, and it is accompanied by large mass transfer of cathode material towards the substrate/treated article 1 being coated.

The above-mentioned process develops in an avalanche-like manner. The internal resistance of the storage system is low, providing cathode spot generation, which can be enhanced when power is supplied to the auxiliary solenoid 13 of magnetron sputtering-initiation system, such that the magnetic field of the auxiliary solenoid compensates the magnetic field of the fixed permanent magnets 10 or the main solenoid 11, respectively.

When the control pulse arrives at the switchboard of the auxiliary solenoid 19 with a delay of not more than 2 msec, it enables the solenoid 12. Cathode spots of the arc discharge being generated on the surface transform the electrical discharges in the auxiliary discharge gap into arc discharges. The transformation is followed by the ejection of ionized atoms of cathode material into main discharge gap. It raises the electrical conductance of the main discharge gap and promotes the development of the main arc discharge. High energy is required to generate the main discharge, it is accompanied by a large mass transfer of cathode material towards the substrate/treated article 1 being coated.

Pulsed vacuum arc discharge occurs between the cathode 4 and the main anode 5 at the expense of the energy stored in the capacitive storage 6. The greatest portion of electrons (approximately 80-90% of the total discharge current) passes to the anode 5. The remaining electrons compensate for the charge of carbon ions moving toward the treated article, thereby providing generation of a quasi-neutral plasma beam of the cathode material. The capacitive storage 6 discharges over the circuit consisting of the consumable cathode 4 and the anode 5.

At the initial moment of arc discharge in the main discharge gap, switch 18 is closed and storage system 15 starts charging. At this moment the storage battery 6 is discharged, and the voltage is lowered to a level insufficient for arc discharge to be supported. The discharge is dying and the storage battery 6 starts charging. The time constants for the electric circuits of the discharge of system have been estimated and a repetition frequency of >30 Hz is possible to repeat the described operation cycle.

The energy characteristics of the (target material) plasma beam affect the properties of the coating, whether diamond-like carbon coatings or other hard coatings, on the treated articles. If the beam energy is too low, formation of a film with predominantly diamond-type bonding is not feasible. If the beam energy is too high, irradiation defects accumulate in the coating and prevents the formation of diamond-like bonds. Since carbon or other coatings exhibit a variety of allotropic modifications, the possibility of modifying energy characteristics of the ion beam within a wide range opens opportunities for producing coatings with predetermined characteristics.

By varying the inductance value (for example through changing the number of turns), the discharge pulse duration, and the ion beam energy characteristics, the erosion factor of the consumable cathode and the angle of deflection of the plasma flow may be controlled.

1. A pulsed plasma source for depositing in vacuum a coating on a substrate, comprising:
a magnetron with a consumable cathode and an anode, said cathode and anode having a common geometrical axis and being electrically coupled to a capacitive storage shunted to a dc charger, and said anode being the proper anode of the magnetron and at the same time being an auxiliary anode of said pulsed plasma source, said cathode and anode making together with the magnetron a magnetron sputtering-initiation system for pulsed arc discharge of a plasma consisting of ionized atoms sputtered from the surface of said cathode,
a means for generating magnetic fields in said magnetron sputtering-initiation system comprising fixed permanent magnets or one main solenoid;
a main anode of said pulsed plasma source, said main anode being accommodated in front of said auxiliary anode;
a means for controlling said carbon plasma beam comprising one solenoid of an ion-optical system being accommodated in front of said main anode in the vacuum chamber;
a means for storage of electrical power from a dc power supply source comprising at least one auxiliary storage system for initiation of discharge with capacitance sufficiently large to store the required quantity of energy for the operation of said magnetron sputtering-initiation system and for initiation-excitation of a pulsed arc discharge, said storage system being switched periodically to provide a voltage between said cathode and said auxiliary anode.

2. The pulsed source of claim 1, characterized in that it comprises:
one auxiliary solenoid for generation and flexible control of magnetic fields in said magnetron sputtering-initiation system;
one external solenoid of said ion-optical system being accommodated outside the vacuum chamber, in front of and surrounding said main anode and said auxiliary anode and being electrically connected with said main anode;
a control means for said pulsed plasma source comprising:
a pulse-train generator;
a control circuit for triggering of said initiation discharge circuit;
a trigger of said initiation discharge circuit;
a switchboard with switched power supply channel for said auxiliary solenoid of said magnetron sputtering-initiation system being synchronized with delay relative to the fronts of initiating pulses in the gap between said cathode and said auxiliary anode and served for compensation of magnetic field generated by said main solenoid of said magnetron sputtering-initiation system;
a power supply unit for solenoids and power unit for a control unit.

3. The pulsed plasma source of claim 1, characterized in that said cathode material can be graphite or metal, including tungsten, titanium, copper and other metals and alloys and other composite materials as well as alloys and mixtures of graphite with tungsten or other metals or other intermetallic compounds.

4. The pulsed plasma source of claim 1, characterized in that said cathode is in the form of a circle, an ellipse or a polygon.

5. The pulsed plasma source of claim 1, characterized in that said anode and said auxiliary anode are in the shape of a hollow cylinder or a hollow prism and the side wall of said cylinder or prism being formed by rods, the longitudinal axis of said rods being parallel with the longitudinal axis of said cylinder or prism, as well as a set of connected rings in the shape of a torous;

6. The pulsed plasma source of claim 1, characterized in that said controlled switch comprises a control unit to determine an operational algorithm of said magnetron sputtering-initiation system.

7. The pulsed plasma source of claim 2, characterized in that it comprises an auxiliary solenoid of said magnetron sputtering-initiation system electrically connected with said target.
